(19) United States
(12) Patent Application Publication
(10) Pub. No.: US 2026/0221164 A1
(43) Pub. Date: Jul. 30, 2026

(54) MAGNETIC ELEMENT, MAGNETIC ARRAY, AND METHOD FOR MANUFACTURING MAGNETIC ELEMENT

(71) Applicant: TDK Corporation, Tokyo (JP)

(72) Inventor: Tomoyuki SASAKI, Tokyo (JP)

(21) Appl. No.: 19/142,781

(22) PCT Filed: Feb. 15, 2023
(86) PCT No.: PCT/JP2023/005134

§ 371 Date: Jun. 24, 2025

(51) Int. Cl. G11C 5/06; G11C 11/16; H10B 61/00; H10N 50/01; H10N 50/10; H10W 40/22

(52) U.S. Cl. CPC G11C 5/063; G11C 11/161; H10B 61/22; H10N 50/01; H10N 50/10; H10W 40/228

(57) ABSTRACT

This magnetic element includes a spin-orbit torque wiring, a laminate, a heat dissipation structure, and a first conductor. The laminate is connected to a first surface of the spin-orbit torque wiring and includes a first ferromagnetic layer. The heat dissipation structure has a plurality of projecting portions protruding in a lamination direction from a second surface opposing the first surface of the spin-orbit torque wiring. The first conductor comes into contact with at least one of the plurality of projecting portions and is electrically connected to the spin-orbit torque wiring.

### TECHNICAL FIELD

The present invention relates to a magnetic element, a magnetic array, and a method for manufacturing a magnetic element.

### BACKGROUND ART

Giant magnetoresistance (GMR) elements constituted of a multilayer film having ferromagnetic layers and a nonmagnetic layer, and tunnel magnetoresistance (TMR) elements using an insulating layer (a tunnel barrier layer, a barrier layer) as a nonmagnetic layer are known as magnetoresistance effect elements. Magnetoresistance effect elements can be applied to magnetic sensors, high-frequency components, magnetic heads, and magnetic random access memories (MRAM).

An MRAM is a storage element in which magnetoresistance effect elements are integrated. An MRAM allows reading and writing of data utilizing characteristics of magnetoresistance effect elements whose resistance varies if magnetization directions of two ferromagnetic layers sandwiching a nonmagnetic layer therebetween in a magnetoresistance effect element vary. For example, the magnetization directions of ferromagnetic layers are controlled utilizing a magnetic field generated by a current. In addition, for example, the magnetization directions of ferromagnetic layers are controlled utilizing a spin transfer torque (STT) generated when a current flows in a lamination direction of magnetoresistance effect elements.

When the magnetization directions of ferromagnetic layers are rewritten utilizing an STT, a current is caused to flow in the lamination direction of the magnetoresistance effect elements. A writing current may cause deterioration in characteristics of the magnetoresistance effect elements.

In recent years, attention has been focused on methods requiring no current to flow in the lamination direction of magnetoresistance effect elements at the time of writing (for example, Patent Document 1). One of the methods is a writing method utilizing a spin-orbit torque (SOT). An SOT is induced due to a spin current generated by a spin-orbit interaction or a Rashba effect in an interface between different kinds of materials. A current for inducing an SOT into magnetoresistance effect elements flows in a direction intersecting the lamination direction of the magnetoresistance effect elements. That is, there is no need for a current to flow in the lamination direction of the magnetoresistance effect elements, and thus extended lifespans of the magnetoresistance effect elements are expected.

### CITATION LIST

### Patent Document

Patent Document 1: Japanese Unexamined Patent Application, First Publication No. 2017-216286

### SUMMARY OF INVENTION

### Technical Problem

In magnetoresistance effect elements utilizing a spin-orbit torque (SOT), heavy metals are often used for wirings in order to inject more spins into a ferromagnetic layer. A wiring containing a heavy metal has a high resistance and is likely to generate heat. If a wiring generates excessive heat, the wiring may break and an element may be destroyed.

The present invention has been made in consideration of the foregoing circumstances, and an object thereof is to provide a magnetic element and a magnetic array, in which heat dissipation efficiency of elements can be enhanced. In addition, another object thereof is to provide an easy method for manufacturing such an element.

### Solution to Problem

This magnetic element includes a spin-orbit torque wiring, a laminate, a heat dissipation structure, and a first conductor. The laminate is connected to a first surface of the spin-orbit torque wiring and includes a first ferromagnetic layer. The heat dissipation structure has a plurality of projecting portions protruding in a lamination direction from a second surface opposing the first surface of the spin-orbit torque wiring. The first conductor comes into contact with at least one of the plurality of projecting portions and is electrically connected to the spin-orbit torque wiring.

### Advantageous Effects of Invention

The magnetic element and the magnetic array according to the present disclosure have high heat dissipation efficiency of elements, In addition, the method for manufacturing a magnetic element according to the present disclosure allows easy production of elements having high heat dissipation efficiency.

### BRIEF DESCRIPTION OF DRAWINGS

FIG. 1 A circuit diagram of a magnetic array according to a first embodiment.

FIG. 2 A cross-sectional view of a characteristic portion of the magnetic array according to the first embodiment.

FIG. 3 A cross-sectional view of a magnetoresistance effect element according to the first embodiment.

FIG. 4 Another cross-sectional view of the magnetoresistance effect element according to the first embodiment.

FIG. 5 An explanatory view of a method for manufacturing the magnetoresistance effect element according to the first embodiment.

FIG. 6 An explanatory view of the method for manufacturing the magnetoresistance effect element according to the first embodiment.

FIG. 7 An explanatory view of the method for manufacturing the magnetoresistance effect element according to the first embodiment.

FIG. 8 An explanatory view of the method for manufacturing the magnetoresistance effect element according to the first embodiment.

FIG. 9 An explanatory view of the method for manufacturing the magnetoresistance effect element according to the first embodiment.

FIG. 10 An explanatory view of the method for manufacturing the magnetoresistance effect element according to the first embodiment.

FIG. 11 A cross-sectional view of a magnetoresistance effect element according to a second embodiment.

FIG. 12 Another cross-sectional view of the magnetoresistance effect element according to the second embodiment.

FIG. 13 A cross-sectional view of a magnetoresistance effect element according to a third embodiment.

FIG. 14 Another cross-sectional view of the magnetoresistance effect element according to the third embodiment.

FIG. 15 A cross-sectional view of a magnetoresistance effect element according to a fourth embodiment.

FIG. 16 A cross-sectional view of a magnetoresistance effect element according to a fifth embodiment.

FIG. 17 A cross-sectional view of a magnetization rotation element according to a sixth embodiment.

### DESCRIPTION OF EMBODIMENTS

Hereinafter, the present embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present invention is not limited thereto and can be suitably changed and performed within a range in which the effects of the present invention are exhibited.

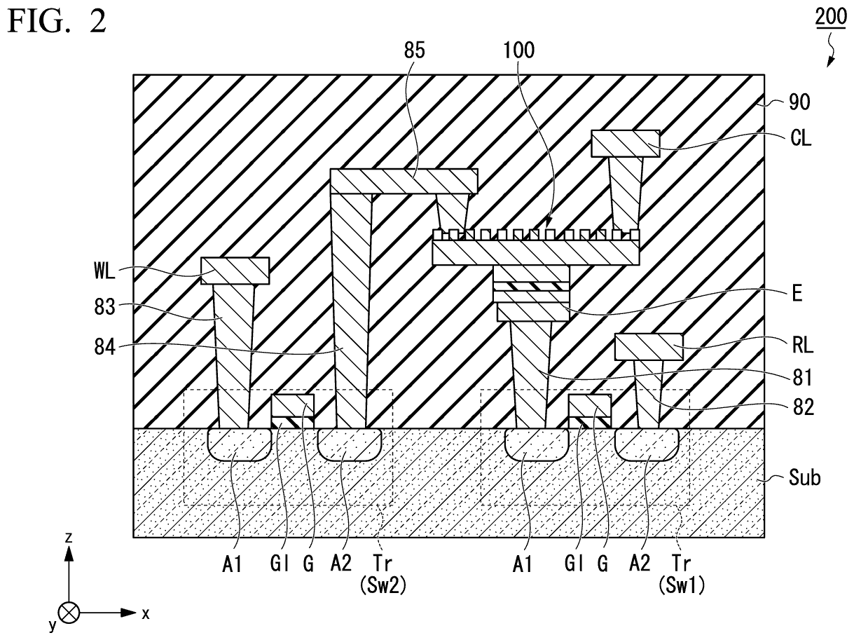

First, directions will be defined. One direction on a surface of a substrate Sub, which will be described below (refer to FIG. 2) will be regarded as an x direction, and a direction orthogonal to the x direction will be regarded as a y direction. For example, the x direction is a longitudinal direction of a spin-orbit torque wiring 20. A z direction is a direction orthogonal to the x direction and the y direction. The z direction is an example of a lamination direction in which layers are laminated. Hereinafter, the positive z direction may be expressed as “upward”, and the negative z direction may be expressed as “downward”. The upward-downward direction does not necessarily coincide with a direction in which gravity is applied.

In this specification, for example, the expression “extending in the x direction” means that the dimension in the x direction is larger than the smallest dimension among respective dimensions in the x direction, the y direction, and the z direction. The same applies to the cases of extending in other directions.

### First Embodiments

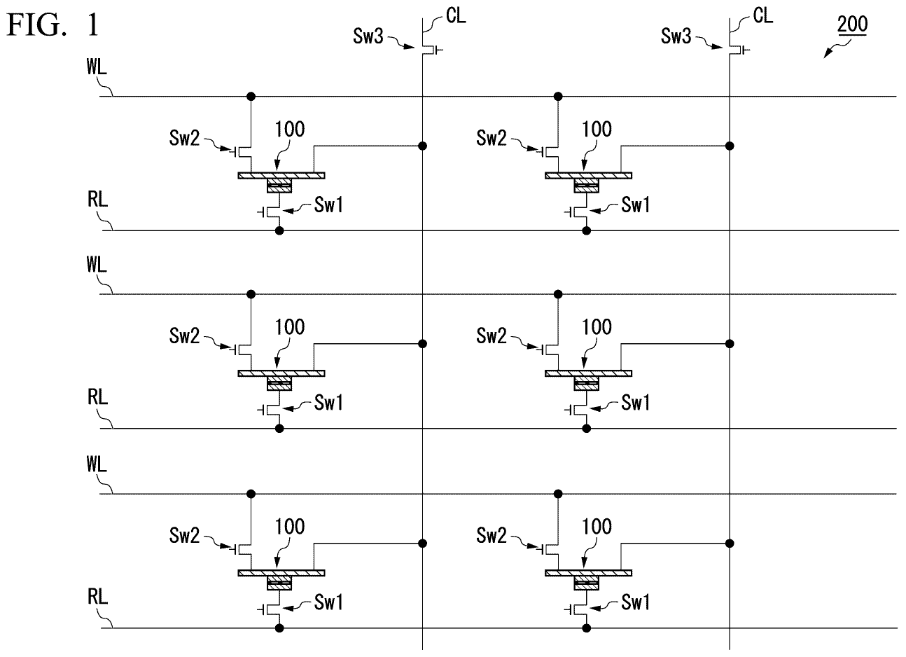

FIG. 1 is a circuit diagram of a magnetic array 200 according to a first embodiment. The magnetic array 200 includes a plurality of magnetoresistance effect elements 100, a plurality of writing wirings WL, a plurality of common wirings CL, a plurality of reading wirings RL, a plurality of first switching elements Sw1, a plurality of second switching elements Sw2, and a plurality of third switching elements Sw3. For example, the magnetic array 200 is a magnetic memory in which the magnetoresistance effect elements 100 are arrayed in an array shape. The magnetoresistance effect element 100 is an example of a magnetic element.

Each of the writing wirings WL electrically connects a power source to one or more magnetoresistance effect elements 100, Each of the common wirings CL is a wiring used at times of both writing and reading data. Each of the common wirings CL electrically connects a reference potential to one or more magnetoresistance effect elements 100. For example, the reference potential is a ground potential. The common wiring CL may be provided in each of the plurality of magnetoresistance effect elements 100 or may be provided across the plurality of magnetoresistance effect elements 100. Each of the reading wirings RL electrically connects the power source to one or more magnetoresistance effect elements 100. The power source is connected to the magnetic array 200 when in use.

Each of the magnetoresistance effect elements 100 is connected to each of the first switching element Sw1, the second switching element Sw2, and the third switching element Sw3. The first switching element Sw1 is connected between the magnetoresistance effect element 100 and the reading wiring RL. The second switching element Sw2 is connected between the magnetoresistance effect element 100 and the writing wiring WL. The third switching element Sw3 is connected to the common wiring CL across the plurality of magnetoresistance effect elements 100.

If a predetermined second switching element Sw2 and a predetermined third switching element Sw3 are turned on, a writing current flows between the writing wiring WL and the common wiring CL connected to a predetermined magnetoresistance effect element 100. Due to a writing current flowing therethrough, data is written in the predetermined magnetoresistance effect element 100. If a predetermined first switching element Sw1 and a predetermined third switching element Sw3 are turned on, a reading current flows between the common wiring CL and the reading wiring RL connected to a predetermined magnetoresistance effect element 100. Due to a reading current flowing therethrough, data is read from the predetermined magnetoresistance effect element 100. The first switching elements Sw1, the second switching elements Sw2, and the third switching elements Sw3 are elements controlling a flow of a current. For example, the first switching elements Sw1, the second switching elements Sw2, and the third switching elements Sw3 may be transistors, elements such as ovonic threshold switches (OTS) utilizing phase change in a crystal layer, elements such as metal insulator transfer (MIT) switches utilizing variation in a band structure, elements such as Zener diodes and avalanche diodes utilizing a breakdown voltage, or elements whose conductivity varies in accordance with variation in atom positions.

In the magnetic array 200 shown in FIG. 1, the magnetoresistance effect elements 100 connected to the same common wiring CL share the third switching element Sw3. The third switching element Sw3 may be provided in each of the magnetoresistance effect elements 100. In addition, the third switching element Sw3 may be provided in each of the magnetoresistance effect elements 100, and the magnetoresistance effect elements 100 connected to the same wiring may share the first switching element Sw1 or the second switching element Sw2.

FIG. 2 is a cross-sectional view of a characteristic portion of the magnetic array 200 according to the first embodiment. FIG. 2 is a cross section of the magnetoresistance effect element 100 cut along an xz plane passing through the center of the width of the spin-orbit torque wiring 20 (which will be described below) in the y direction.

The first switching element Sw1 and the second switching element Sw2 shown in FIG. 2 are transistors Tr. The third switching element Sw3 is electrically connected to the common wiring CL and is located at a position different in the y direction from the position shown in FIG. 2, for example. For example, the transistors Tr are field effect transistors each having a gate electrode G, a gate insulating film GI, and a first active area A1 and a second active area A2 formed on the substrate Sub. The first active area A1 and the second active area A2 are referred to as sources or drains depending on the flowing direction of a current. For example, the substrate Sub is a semiconductor substrate.

The magnetoresistance effect element 100 and the first switching element Sw1 are connected through an electrode E and a via wiring 81. The reading wiring RL and the first switching element Sw 1 are connected through a via wiring 82. The writing wiring WL and the second switching element Sw2 are connected through a via wiring 83. The magnetoresistance effect element 100 and the second switching element Sw2 are connected through a via wiring 84 and an in-plane wiring 85. The via wirings 81, 82, 83, and 84, the in-plane wiring 85, and the electrode E are conductive.

Areas around the magnetoresistance effect element 100 and the transistors Tr are covered by an insulating layer 90. The insulating layer 90 is an insulating layer providing insulation between wirings of a multilayer wiring or between elements. For example, the insulating layer 90 is made of silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

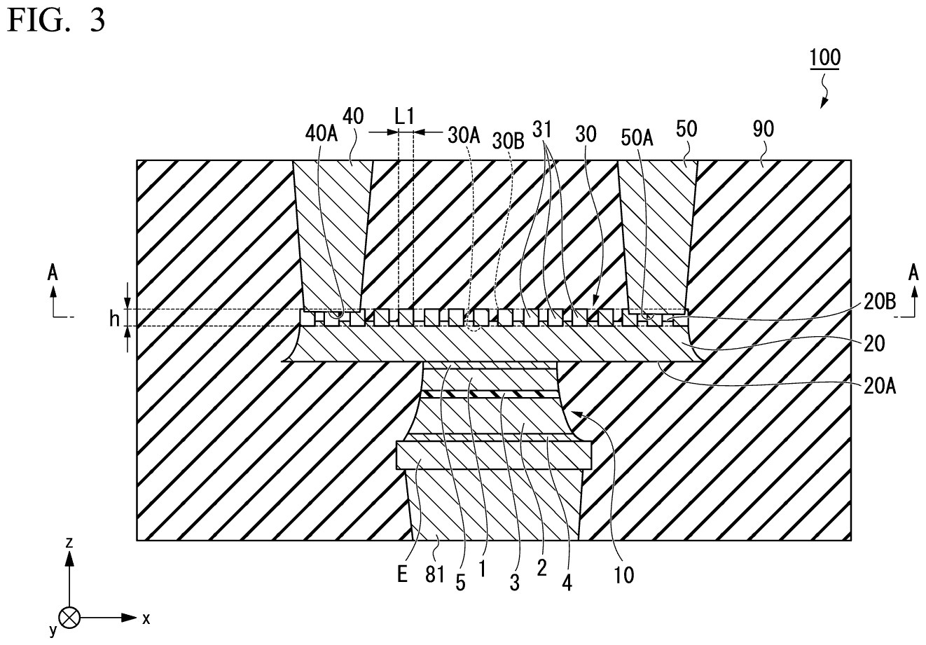

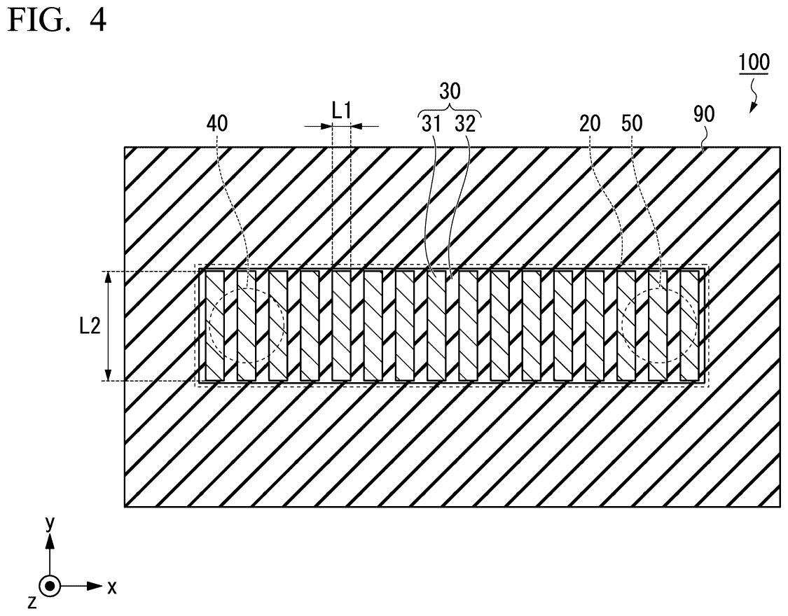

FIG. 3 is a cross-sectional view of the magnetoresistance effect element 100 according to the first embodiment. FIG. 3 is a cross section of the magnetoresistance effect element 100 cut along an xz plane passing through the center of the width of the spin-orbit torque wiring 20 in the y direction. FIG. 4 is another cross-sectional view of the magnetoresistance effect element 100 according to the first embodiment. FIG. 4 is a cross section cut along line A-A in FIG. 3.

For example, the magnetoresistance effect element 100 includes a laminate 10, the spin-orbit torque wiring 20, a heat dissipation structure 30, a first conductor 40, and a second conductor 50.

The magnetoresistance effect element 100 is a magnetic element utilizing a spin-orbit torque (SOT) and may be referred to as a spin-orbit torque-type magnetoresistance effect element, a spin injection-type magnetoresistance effect element, or a spin current magnetoresistance effect element.

The magnetoresistance effect element 100 is an element which records and saves data. The magnetoresistance effect element 100 records data using a resistance value of the laminate 10 in the z direction. The resistance value of the laminate 10 in the z direction varies when a writing current is applied along the spin-orbit torque wiring 20 and spins are injected into the laminate 10 from the spin-orbit torque wiring 20. The resistance value of the laminate 10 in the z direction can be read by applying a reading current in the z direction of the laminate 10.

The laminate 10 is connected to a first surface 20A of the spin-orbit torque wiring 20. The laminate 10 is a columnar body. For example, the shape of the laminate 10 in a plan view in the z direction is a circular shape, an oval shape, or a quadrangular shape. For example, side surfaces of the laminate 10 are inclined with respect to the z direction.

For example, the laminate 10 includes a first ferromagnetic layer 1, a second ferromagnetic layer 2, a nonmagnetic layer 3, a base layer 4, and a cap layer 5. In the laminate 10, the resistance value varies in accordance with the difference in relative angle of the magnetization of the first ferromagnetic layer 1 and the second ferromagnetic layer 2 sandwiching the nonmagnetic layer 3 therebetween.

For example, the first ferromagnetic layer 1 faces the spin-orbit torque wiring 20. The first ferromagnetic layer 1 may directly come into contact with the spin-orbit torque wiring 20 or may indirectly come into contact with it with the cap layer 5 therebetween. For example, the first ferromagnetic layer 1 is closer to the spin-orbit torque wiring 20 than the second ferromagnetic layer 2.

Spins are injected into the first ferromagnetic layer 1 from the spin-orbit torque wiring 20. The magnetization of the first ferromagnetic layer 1 receives a spin-orbit torque (SOT) due to injected spins so that the orientation direction thereof varies. The first ferromagnetic layer 1 is referred to as a magnetization free layer.

The first ferromagnetic layer 1 includes a ferromagnetic body. For example, the ferromagnetic body is a metal selected from the group consisting of Cr, Mn, Co, Fe, and Ni; an alloy containing one or more kinds of these metals; an alloy containing at least one or more kinds of elements of these metals, B, C, and N; or the like. For example, the ferromagnetic body is an alloy of Co-Fe, Co-Fe-B, Ni-Fe, or Co-Ho alloy; a Sm-Fe alloy; a Fe-Pt alloy; a Co-Pt alloy; or a CoCrPt alloy.

The first ferromagnetic layer 1 may contain a Heusler alloy. The Heusler alloy contains an intermetallic compound having a chemical composition of XYZ or X₂YZ. X represents a transition metal element or a noble metal element of the Co group, the Fe group, the Ni group, or the Cu group on the periodic table. Y represents a transition metal of the Mn group, the V group, the Cr group, or the Ti group, or an element kind of X. Zrepresents a typical element of Group III to Group V. For example, the Heusler alloy consists of Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The second ferromagnetic layer 2 faces the first ferromagnetic layer 1 with the nonmagnetic layer 3 sandwiched therebetween. The second ferromagnetic layer 2 includes a ferromagnetic body. The orientation direction of the magnetization of the second ferromagnetic layer 2 is less likely to vary than that of the magnetization of the first ferromagnetic layer 1 when a predetermined external force is applied thereto. The second ferromagnetic layer 2 is referred to as a magnetization fixed layer or a magnetization reference layer. The laminate 10 shown in FIG. 3 has the magnetization fixed layer closer to the substrate Sub than the magnetization free layer and is referred to as a bottom pin structure.

A material similar to that constituting the first ferromagnetic layer 1 is used as a material constituting the second ferromagnetic layer 2.

The second ferromagnetic layer 2 may have a synthetic antiferromagnetic structure (SAF structure). A synthetic antiferromagnetic structure is constituted of two magnetic layers with a nonmagnetic layer sandwiched therebetween. The second ferromagnetic layer 2 may have two magnetic layers and a spacer layer sandwiched therebetween. Due to antiferromagnetic coupling between two ferromagnetic layers, a coercive force of the second ferromagnetic layer 2 increases. For example, the ferromagnetic layer is made of IrMn, PtMn, or the like. For example, the spacer layer contains at least one selected from the group consisting of Ru, Ir, and Rh.

The nonmagnetic layer 3 is sandwiched between the first ferromagnetic layer 1 and the second ferromagnetic layer 2. The nonmagnetic layer 3 includes a nonmagnetic body. When the nonmagnetic layer 3 is an insulator (when it is a tunnel barrier layer), for example, Al₂O₃, SiO₂, MgO, MgAl₂O₄, or the like can be used as a material thereof. In addition to these, a material or the like in which a part of Al, Si, or Mg is replaced with Zn, Be, or the like can also be used. Among these, since MgO and MgAl₂O₄ are materials capable of realizing coherent tunneling, spins can be efficiently injected.

When the nonmagnetic layer 3 is made of a metal, Cu, Au, Ag, or the like can be used as a material thereof. Moreover, when the nonmagnetic layer 3 is constituted of a semiconductor, Si, Ge, CuInSe₂, CuGaSe₂, Cu(In, Ga)Se₂, or the like can be used as a material thereof.

For example, the base layer 4 is located between the second ferromagnetic layer 2 and the electrode E. The base layer 4 may be omitted.

For example, the base layer 4 includes a buffer layer and a seed layer. The buffer layer is a layer relieving lattice mismatching between different crystals, The seed layer enhances the crystallinity of the layer laminated on the seed layer. For example, the seed layer is formed on the buffer layer.

For example, the buffer layer is made of a simple substance (Ta), tantalum nitride (TaN), copper nitride (CuN), titanium nitride (TN), or nickel aluminum (NiAl). For example, the seed layer is made of Pt, Ru, Zr, a NiCr alloy, or NiFeCr.

The cap layer 5 is on the second ferromagnetic layer 2. For example, the cap layer 5 strengthens magnetic anisotropy of the second ferromagnetic layer 2. For example, the cap layer 5 strengthens perpendicular magnetic anisotropy of the second ferromagnetic layer 2. For example, the cap layer 5 is made of oxide magnesium, W, Ta, Mo, or the like, For example, the film thickness of the cap layer 5 is 0.5 nm to 5.0 nm.

The laminate 10 may have a layer other than the first ferromagnetic layer 1, the second ferromagnetic layer 2, the nonmagnetic layer 3, the base layer 4, and the cap layer 5.

For example, the spin-orbit torque wiring 20 extends in the x direction such that the length in the x direction is longer than that in the y direction when viewed in the z. direction. A writing current flows in the x direction along the spin-orbit torque wiring 20 between the first conductor 40 and the second conductor 50.

The spin-orbit torque wiring 20 induces a spin current due to a spin-orbit interaction and an interfacial Rashba effect and injects spins into the first ferromagnetic layer 1. For example, the spin-orbit torque wiring 20 applies a spin-orbit torque (SOT) to the magnetization of the first ferromagnetic layer 1 by an amount with which the magnetization of the first ferromagnetic layer I can be reversed.

A spin Hall effect is a phenomenon in which a spin current is induced in a direction orthogonal to the flowing direction of a current based on a spin-orbit interaction when a current flows. The spin Hall effect is in common with a normal Hall effect in that kinetic (moving) charge (electrons) can bend the kinetic (moving) direction. In the normal Hall effect, the kinetic direction of kinetic charged particles in a magnetic field bends due to a Lorentz force. In contrast, in the spin Hall effect, even if there is no magnetic field, the moving direction of spins bends simply due to movement of electrons (simply due to flowing currents).

For example, if a current flows in the spin-orbit torque wiring 20, for example, first spins polarized in the negative y direction bend in the negative z direction from the x direction that is the traveling direction, and second spins polarized in the positive y direction bend in the positive z direction from the x direction that is the traveling direction.

In a nonmagnetic body (a material that is not a ferromagnetic body), the number of electrons in the first spins generated due to the spin Hall effect and the number of electrons in the second spins are the same. That is, the number of electrons in the first spins toward the negative z direction and the number of electrons in the second spins toward the positive z direction are the same. Since flows of charge are offset each other in movement of the first spins and the second spins in the z direction, the current amount becomes zero. A spin current accompanying no current is particularly referred to as a pure spin current.

When a flow of electrons in the first spins is expressed as J_{↑}, a flow of electrons in the second spins is expressed as J_{↓}, and a spin current is expressed as J_{S}, these are defined as J_{S}=J_{↑}-J₇₅ . The spin current J_{S} is generated in the z direction. The first spins are injected into the first ferromagnetic layer 1 from the spin-orbit torque wiring 20.

The spin-orbit torque wiring 20 contains any of a metal, an alloy, an intermetallic compound, a metal boride, a metal carbide, a metal silicide, a metal phosphide, and a metal nitride having a function of generating a spin current.

For example, the spin-orbit torque wiring 20 contains any one selected from the group consisting of a heavy metal whose atomic number is 39 or larger, a metal oxide, a metal nitride, a metal oxynitride, and a topological insulator. In addition, the spin-orbit torque wiring 20 may contain a magnetic material.

For example, the spin-orbit torque wiring 20 contains a nonmagnetic heavy metal as a main component. A heavy metal means a metal having a specific gravity equal to or greater than that of yttrium (Y). For example, a nonmagnetic heavy metal is a nonmagnetic metal having d electrons or f electrons in its outermost shell and having a large atomic number (atomic number 39 or larger). In a nonmagnetic heavy metal, a spin-orbit interaction stronger than those in other metals occurs. A spin Hall effect occurs due to a spin-orbit interaction, and spins are likely to be unevenly distributed inside the spin-orbit torque wiring 20 so that the spin current J_{S} is likely to be generated.

The heat dissipation structure 30 comes into contact with the spin-orbit torque wiring 20. The heat dissipation structure 30 comes into contact with a surface of the spin-orbit torque wiring 20 on a side opposite to the first surface with which the laminate 10 comes into contact.

For example, the heat dissipation structure 30 has a plurality of projecting portions 31 and a plurality of insulating portions 32. Each of the plurality of projecting portions 31 protrudes in the z direction from a second surface 20B of the spin-orbit torque wiring 20. The second surface 20B is a surface opposing the first surface 20A of the spin-orbit torque wiring 20, which is a surface farthest from the laminate 10 in the z direction in the spin-orbit torque wiring 20.

The plurality of projecting portions 31 have a large surface area and are excellent in heat dissipation. In addition, the plurality of projecting portions 31 have a high emissivity due to their shape and are excellent in heat dissipation.

For example, the projecting portions 31 are conductors. For example, the resistivity of the projecting portions 31 may be higher than the resistivity of the spin-orbit torque wiring 20. If the resistivity of the projecting portions 31 is high, shunting of a writing current to the projecting portions 31 side can be curbed, and data writing efficiency can be enhanced.

For example, an average height h of the projecting portions 31 is shorter than an average length L1 of the projecting portions 31 in the x direction. By making the average height h of the projecting portions 31 not excessively high, shunting of a writing current to the projecting portions 31 side can be curbed. In addition, an average length L2 of the projecting portions 31 in the y direction is longer than the average length L1 of the projecting portions 31 in the x direction. If the projecting portions 31 have a major axis in the y direction, a writing current is less likely to flow in the x direction in the projecting portions 31, so that shunting of a writing current to the projecting portions 31 side can be curbed.

For example, the average height h of the projecting portions 31 is 3 nm to 100 nm. For example, the average length L1 of the projecting portions 31 in the x direction is 3 nm to 30 nm. For example, the average length L2 of the projecting portions 31 in the y direction is 3 nm to 100 nm.

Some of the projecting portions 31 may be embedded in the spin-orbit torque wiring 20. For example, in the z direction, a first surface 30A of the heat dissipation structure 30 may be closer to the laminate 10 than the second surface 20B of the spin-orbit torque wiring 20. The first surface 30A of the heat dissipation structure 30 is a surface of the heat dissipation structure 30 on the laminate 10 side, which is a surface coming into contact with the spin-orbit torque wiring 20. For example, the first surface 30A of the heat dissipation structure 30 is a line connecting lower surfaces of the projecting portions 31. If some of the projecting portions 31 are embedded in the spin-orbit torque wiring 20, electrical connection between the projecting portions 31 and the spin-orbit torque wiring 20 is improved.

The insulating portions 32 are insulators. A material similar to that of the insulating layer 90 can be used for the insulating portions 32. Each of the insulating portions 32 is located between adjacent projecting portions 31. The plurality of projecting portions 31 are discontinuous in the x direction due to the insulating portions 32.

The first conductor 40 comes into contact with at least one of the plurality of projecting portions 31. The first conductor 40 is electrically connected to the spin-orbit torque wiring 20. The first conductor 40 contains a conductive material. For example, the first conductor 40 is made of Cu, Al, or Ag.

A part of the first conductor 40 may be embedded in the heat dissipation structure 30. For example, in the z direction, a first surface 40A of the first conductor 40 may be closer to the spin-orbit torque wiring 20 than a second surface 30B of the heat dissipation structure 30. The second surface 30B of the heat dissipation structure 30 is a surface opposing the first surface 30A. For example, the second surface 30B of the heat dissipation structure 30 is a line connecting upper surfaces of the projecting portions 31 at a position not overlapping the first conductor 40 and the second conductor 50 when viewed in the z direction. If a part of the first conductor 40 is embedded in the heat dissipation structure 30, the contact area between the projecting portions 31 and the first conductor 40 increases so that electrical connection between the projecting portions 31 and the first conductor 40 is improved.

The second conductor 50 comes into contact with at least one of the plurality of projecting portions 31. The second conductor 50 comes into contact with at least one of the plurality of projecting portions 31 at a position different from the first conductor 40. The second conductor 50 is electrically connected to the spin-orbit torque wiring 20. The second conductor 50 contains a conductive material and contains a material similar to that of the first conductor 40.

A part of the second conductor 50 may be embedded in the heat dissipation structure 30. For example, in the z direction, a first surface 50A of the second conductor 50 may be closer to the spin-orbit torque wiring 20 than the second surface 30B of the heat dissipation structure 30.

Next, a method for manufacturing the magnetoresistance effect element 100 will be described. The magnetoresistance effect element 100 is formed through a step of laminating each of the layers, and a processing step of processing a part of each of the layers into a predetermined shape. Each of the layers can be laminated using a sputtering method, a chemical vapor deposition (CVD) method, an electron beam evaporation method (EB evaporation method), an atom laser deposition (ALD) method, or the like. Each of the layers can be processed using photolithography or the like.

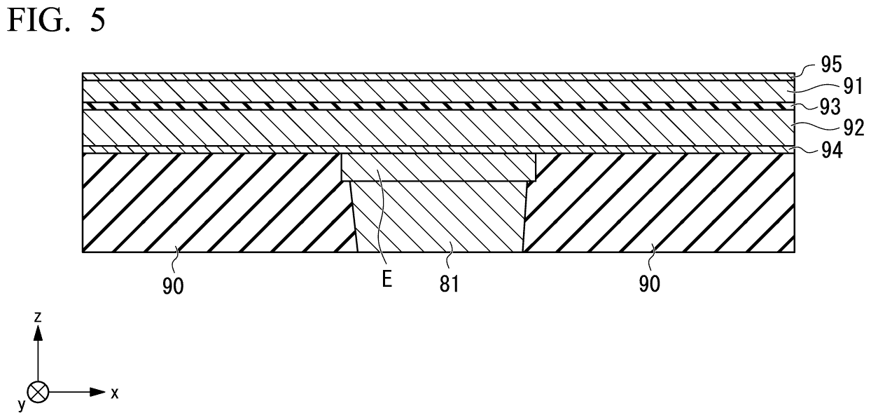

For example, the method for manufacturing the magnetoresistance effect element 100 has a lamination step, a film formation step, a pattern formation step, a coating step, a lift-off step, and a conductor formation step. FIGS. 5 to 10 are explanatory views of an example of the method for manufacturing a magnetoresistance effect element according to the first embodiment.

In the lamination step, a laminate including a first ferromagnetic layer 91 is laminated. For example, as shown in FIG. 5, in the lamination step, a base layer 94, a second ferromagnetic layer 92, a nonmagnetic layer 93, the first ferromagnetic layer 91, and a cap layer 95 are laminated in this order. Next, a laminate of these is processed into a predetermined shape. The base layer 94 becomes the base layer 4. The second ferromagnetic layer 92 becomes the second ferromagnetic layer 2. The nonmagnetic layer 93 becomes the nonmagnetic layer 3. The first ferromagnetic layer 91 becomes the first ferromagnetic layer 1. The cap layer 95 becomes the cap layer 5. The laminate 10 can be obtained through such a procedure.

Next, the area around the laminate 10 is coated with the insulating layer 90.

Further, a part of the insulating layer 90 is removed by chemical mechanical polishing until the cap layer 5 is exposed.

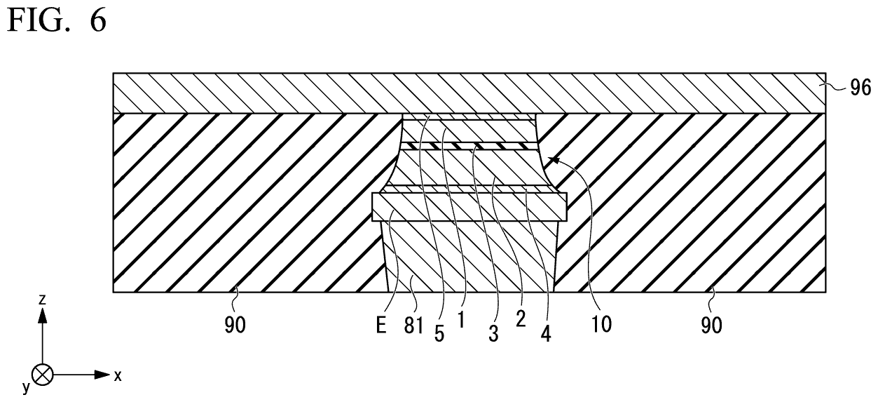

Next, as shown in FIG. 6, the film formation step is performed. In the film formation step, film-formed a spin-orbit torque wiring 96 is performed. The spin-orbit torque wiring 96 is processed into a predetermined shape, and it becomes the spin-orbit torque wiring 20. Here, an example in which the spin-orbit torque wiring 20 and the laminate 10 are processed separately has been described, but processing of these may be performed at the same time.

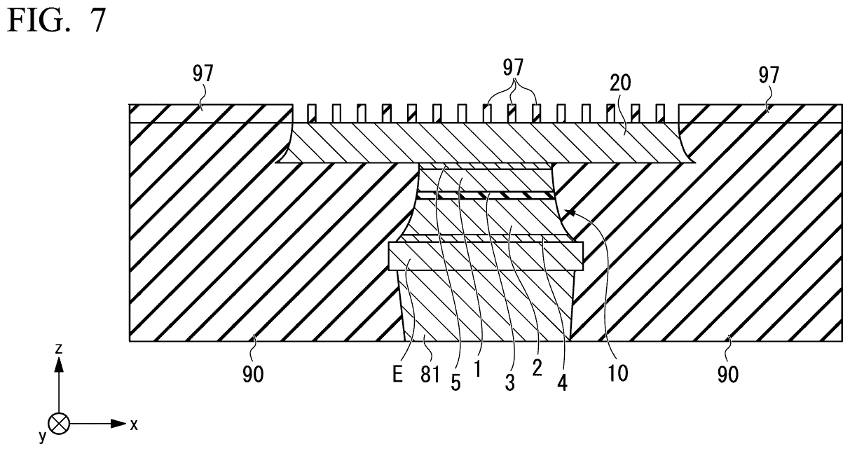

Next, as shown in FIG. 7, the pattern formation step is performed. In the pattern formation step, a sacrificial layer 97 is pattern-formed on the spin-orbit torque wiring 20. For example, the sacrificial layer 97 is a resist. Here, an example in which the sacrificial layer 97 is formed after processing of the spin-orbit torque wiring 20 has been described, but the sacrificial layer 97 may be formed on the spin-orbit torque wiring 96 before processing.

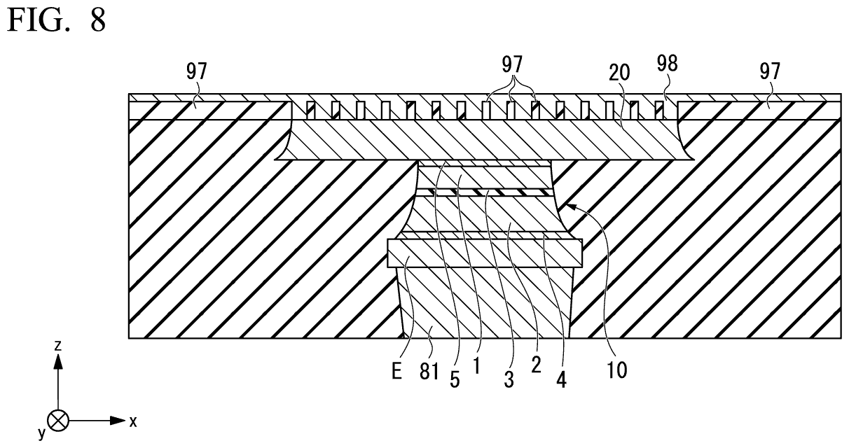

Next, as shown in FIG. 8, the coating step is performed. In the coating step, a heat dissipation layer 98 is film-formed on the spin-orbit torque wiring 20 and the sacrificial layer 97. The spin-orbit torque wiring 20 and the sacrificial layer 97 are coated with the heat dissipation layer 98. When the sacrificial layer 97 is formed on the spin-orbit torque wiring 96 before processing, the heat dissipation layer 98 is film-formed on the spin-orbit torque wiring 96 and the sacrificial layer 97.

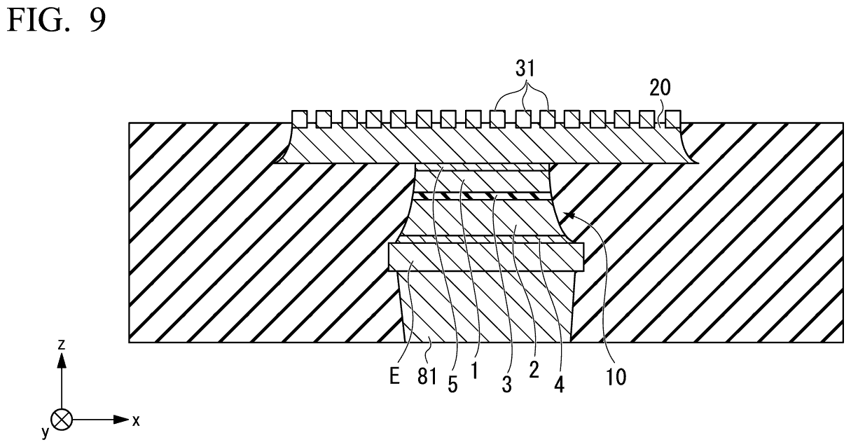

Next, as shown in FIG. 9, the lift-off step is performed. In the lift-off step, the sacrificial layer 97 is lifted off, If the sacrificial layer 97 is lifted off, a part of the heat dissipation layer 98 is removed, and the heat dissipation structure 30 having a plurality of projecting portions 31 is formed. Further, the insulating layer 90 is formed such that the heat dissipation structure 30 is coated.

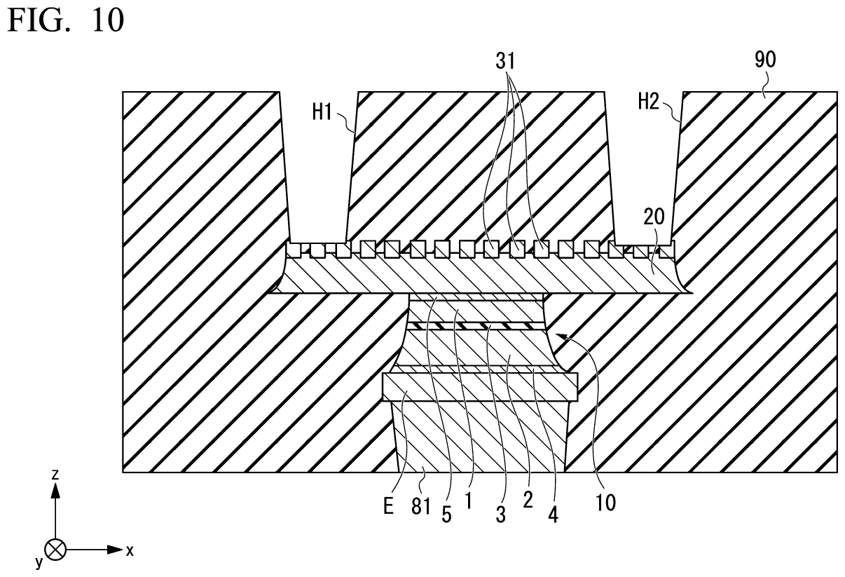

Next, as shown in FIG. 10, the conductor formation step is performed. In the conductor formation step, an opening H1 and an opening H2 are formed at positions overlapping at least one of the plurality of projecting portions 31. If the opening HI is filled with a conductor, the first conductor 40 is formed. If the opening H2 is filled with a conductor, the second conductor 50 is formed.

The magnetoresistance effect element 100 can be obtained by performing each of the steps through the foregoing procedure.

The magnetoresistance effect element 100 according to the first embodiment has the heat dissipation structure 30 having a plurality of projecting portions 31, thereby being excellent in heat dissipation and capable of curbing accumulation of heat in the spin-orbit torque wiring 20. This is because the plurality of projecting portions 31 have a large surface area and a high emissivity due to their shape.

In addition, since the first conductor 40 and the second conductor 50 come into contact with at least one of the plurality of projecting portions 31, electrical connection therebetween can be enhanced. In addition, due to the presence of the plurality of projecting portions 31, it is easy to secure electrical connection even when the formation position of the opening H1 or the opening HI2 has deviated from a desired position due to an alignment error.

### Second Embodiment

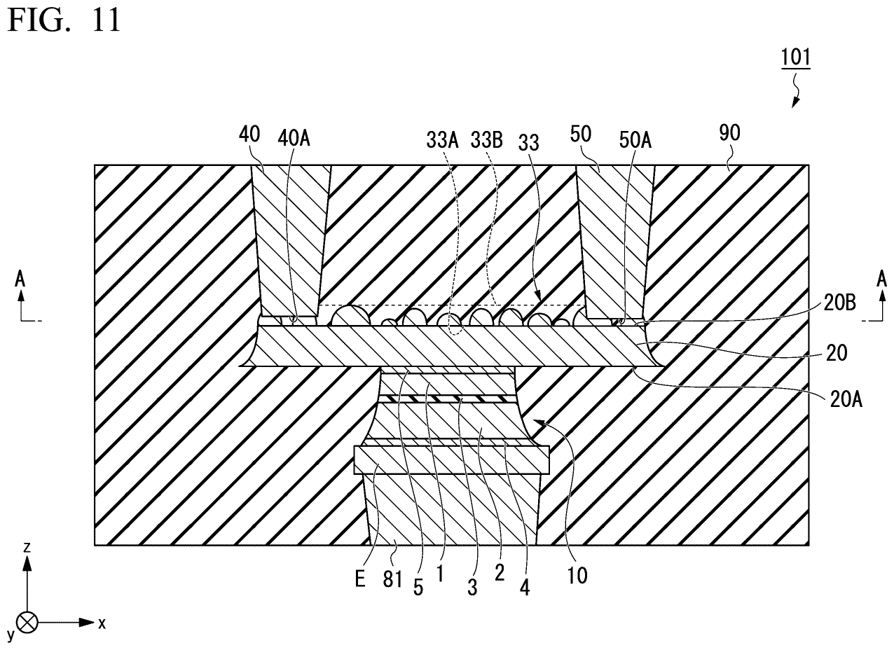

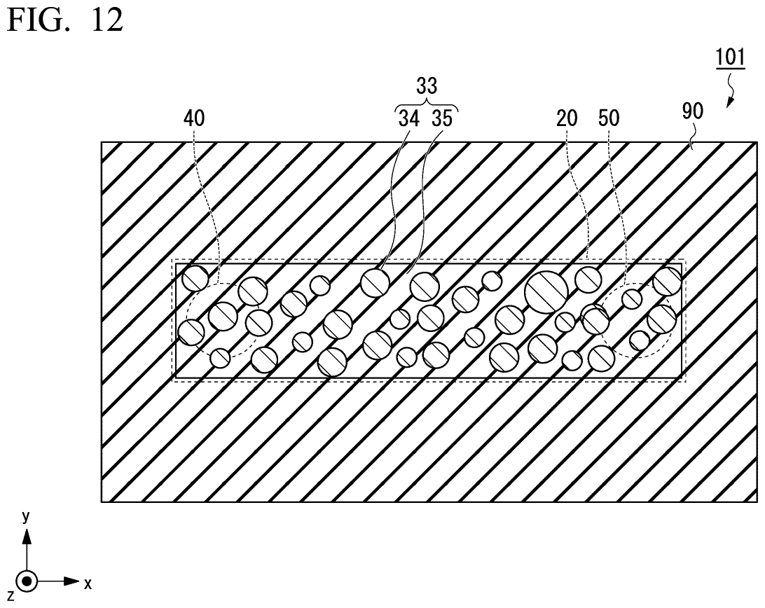

FIG. 11 is a cross-sectional view of a magnetoresistance effect element 101 according to a second embodiment. FIG. 11 is a cross section of the magnetoresistance effect element 101 cut along an xz plane passing through the center of the width of the spin-orbit torque wiring 20 in the y direction. FIG. 12 is another cross-sectional view of the magnetoresistance effect element 101 according to the second embodiment. FIG. 12 is a cross section cut along line A-A in FIG. 11.

The magnetoresistance effect element 101 differs from the magnetoresistance effect element 100 in shape of a heat dissipation structure 33. In the magnetoresistance effect element 101, the same reference signs are applied to the same constituents as those in the magnetoresistance effect element 100, and a description thereof will be omitted.

For example, the heat dissipation structure 33 has a plurality of projecting portions 34 and an insulating portion 35. Each of the plurality of projecting portions 34 protrudes in the z direction from the second surface 20B of the spin-orbit torque wiring 20. The plurality of projecting portions 34 are present within the insulating portion 35 in an island shape.

For example, the projecting portions 34 are conductors. For example, the projecting portions 34 contain a material similar to that of the projecting portions 31.

For example, the projecting portions 34 are crystal grains. If sputtering conditions are adjusted, atoms which have adhered to a film-formed surface move and grow into grains. For example, if the degree of vacuum at the time of film formation is lowered, the film-formed atoms are more likely to grow into grains. For example, the resistivity of the projecting portions 34 may be higher than the resistivity of the spin-orbit torque wiring 20.

For example, the positional relationship of a first surface 33A and a second surface 33B of the heat dissipation structure 33 with respect to other structures may be similar to the positional relationship of the first surface 30A and the second surface 30B of the heat dissipation structure 30 with respect to other structures. The second surface 33B of the heat dissipation structure 33 is an xy plane passing through points in the projecting portions 34 farthest from the spin-orbit torque wiring 20.

The insulating portion 35 is an insulator. The area around each of the projecting portions 34 is coated with the insulating portion 35. A material similar to that of the insulating layer 90 can be used for the insulating portion 35. The projecting portions 34 are discontinuously interspersed in the insulating portion 35.

The first conductor 40 comes into contact with at least one of the plurality of projecting portions 34. The second conductor 50 comes into contact with at least one of the plurality of projecting portions 34.

The magnetoresistance effect element 101 according to the second embodiment exhibits effects similar to those of the magnetoresistance effect element 100 according to the first embodiment.

### Third Embodiment

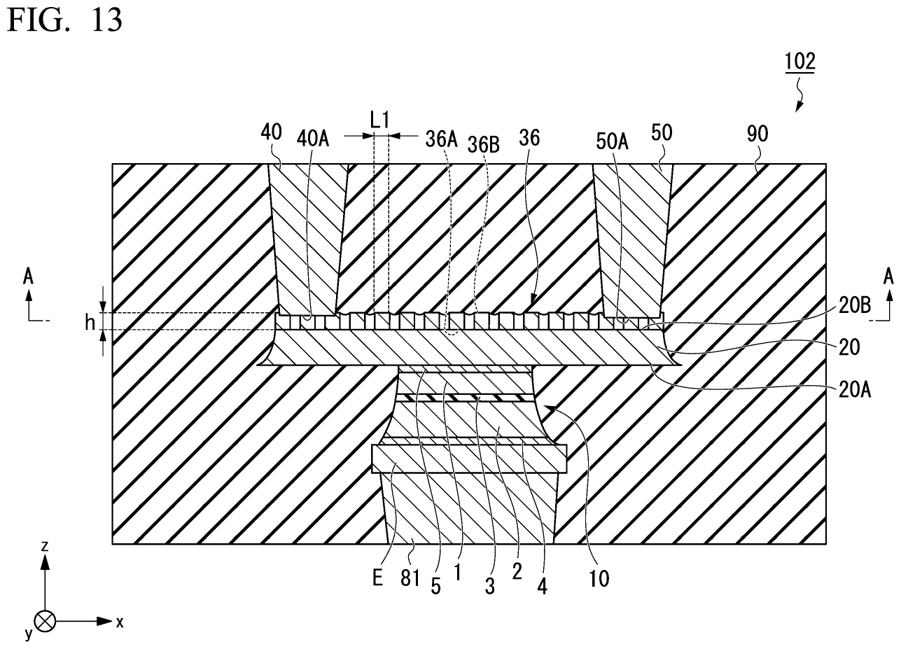

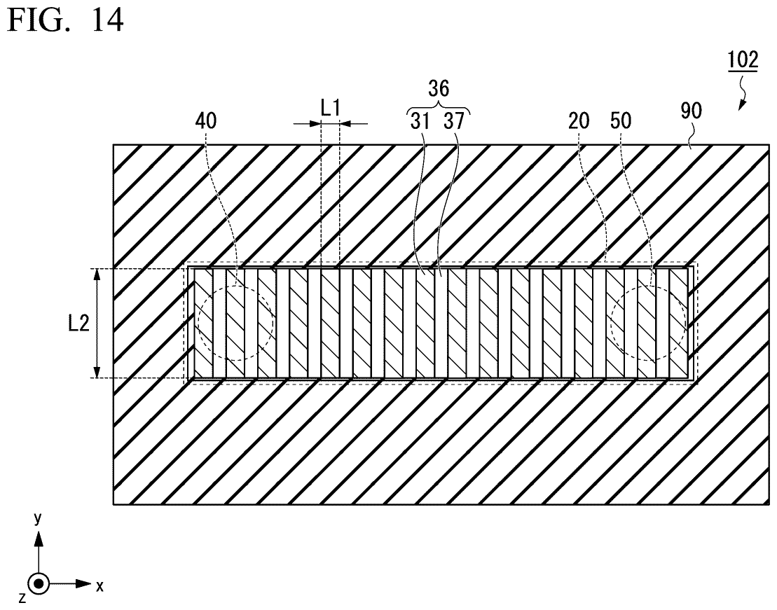

FIG. 13 is a cross-sectional view of a magnetoresistance effect element 102 according to a third embodiment. FIG. 13 is a cross section of the magnetoresistance effect element 102 cut along an xz plane passing through the center of the width of the spin-orbit torque wiring 20 in the y direction. FIG. 14 is another cross-sectional view of the magnetoresistance effect element 102 according to the third embodiment. FIG. 14 is a cross section cut along line A-A in FIG. 13.

The magnetoresistance effect element 101 differs from the magnetoresistance effect element 100 in shape of a heat dissipation structure 36. In the magnetoresistance effect element 101, the same reference signs are applied to the same constituents as those in the magnetoresistance effect element 100, and a description thereof will be omitted.

For example, the heat dissipation structure 36 has a plurality of projecting portions 31 and a plurality of voids 37. The heat dissipation structure 36 differs from the heat dissipation structure 30 in that the voids 37 play the role of the insulating portions 32.

For example, the positional relationship of a first surface 36A and a second surface 36B of the heat dissipation structure 36 with respect to other structures may be similar to the positional relationship of the first surface 30A and the second surface 30B of the heat dissipation structure 30 with respect to other structures.

The insides of the voids 37 are vacuum or filled with gas. The gas may be air or an inert gas. The plurality of projecting portions 31 are discontinuous in the x direction due to the voids 37.

The magnetoresistance effect element 102 according to the third embodiment exhibits effects similar to those of the magnetoresistance effect element 100 according to the first embodiment.

### Fourth Embodiment

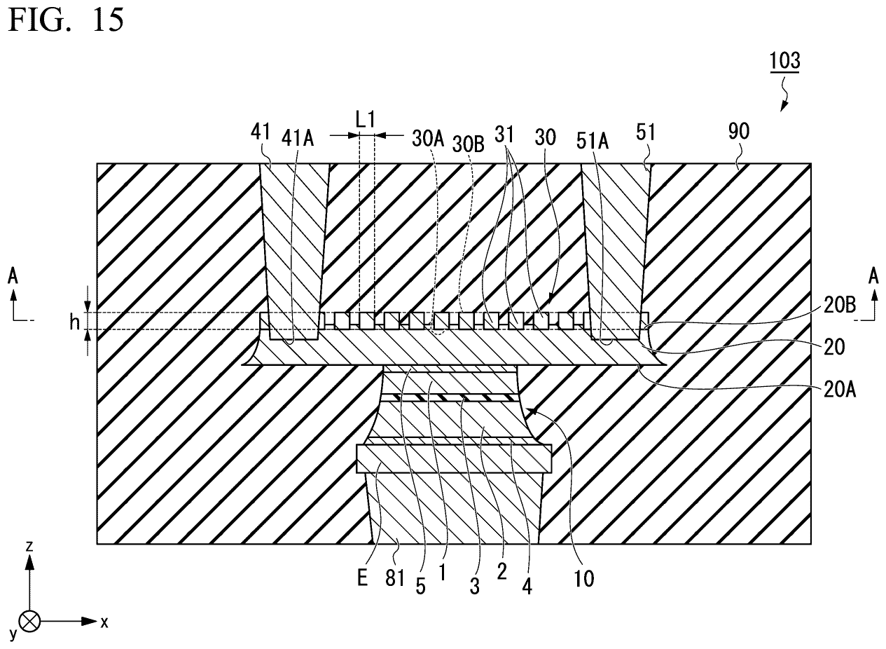

FIG. 15 is a cross-sectional view of a magnetoresistance effect element 103 according to a fourth embodiment. FIG. 15 is a cross section of the magnetoresistance effect element 103 cut along an xz plane passing through the center of the width of the spin-orbit torque wiring 20 in the y direction.

The magnetoresistance effect element 103 differs from the magnetoresistance effect element 100 in shape of a first conductor 41 and a second conductor 51. In the magnetoresistance effect element 103, the same reference signs are applied to the same constituents as those in the magnetoresistance effect element 100, and a description thereof will be omitted.

The first conductor 41 comes into contact with at least one of a plurality of projecting portions 31. The first conductor 41 directly comes into contact with the spin-orbit torque wiring 20. For example, in the z direction, a first surface 41A of the first conductor 41 is closer to the spin-orbit torque wiring 20 than the first surface 30A and the second surface 30B of the heat dissipation structure 30 in the z direction and is closer to the laminate 10 than the second surface 20B of the spin-orbit torque wiring 20. The first conductor 41 contains a material similar to that of the first conductor 40. Since the first conductor 41 directly comes into contact with the spin-orbit torque wiring 20, electrical connection between the first conductor 41 and the spin-orbit torque wiring 20 can be further enhanced.

The second conductor 51 comes into contact with at least one of the plurality of projecting portions 31. The second conductor 51 directly comes into contact with the spin-orbit torque wiring 20. For example, in the z direction, a first surface 51A of the second conductor 51 is closer to the spin-orbit torque wiring 20 than the first surface 30A and the second surface 30B of the heat dissipation structure 30 in the z direction and is closer to the laminate 10 than the second surface 20B of the spin-orbit torque wiring 20. The second conductor 51 contains a material similar to that of the second conductor 50. Since the second conductor 51 directly comes into contact with the spin-orbit torque wiring 20, electrical connection between the second conductor 51 and the spin-orbit torque wiring 20 can be further enhanced.

### Fifth Embodiment

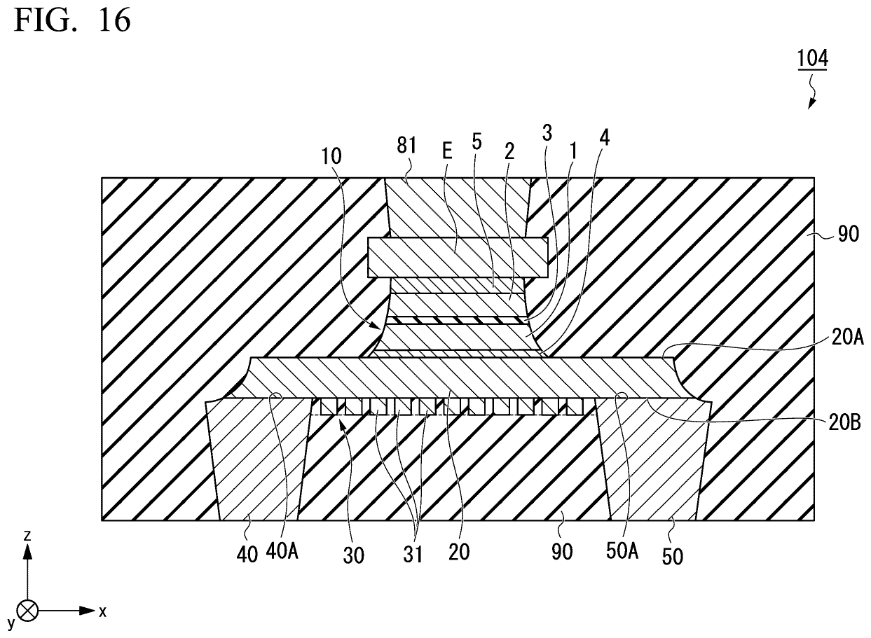

FIG. 16 is a cross-sectional view of a magnetoresistance effect element 104 according to a fifth embodiment. FIG. 16 is a cross section of the magnetoresistance effect element 104 cut along an xz plane passing through the center of the width of the spin-orbit torque wiring 20 in the y direction.

The laminating order of the laminate 10 and the spin-orbit torque wiring 20 in the magnetoresistance effect element 104 differs from the laminating order of the laminate 10 and the spin-orbit torque wiring 20 in the magnetoresistance effect element 100. The laminate 10 is laminated on the spin-orbit torque wiring 20. For example, the base layer 4 is located between the first ferromagnetic layer 1 and the spin-orbit torque wiring 20. For example, the cap layer 5 is located between the second. ferromagnetic layer 2 and the electrode E.

The magnetoresistance effect element 104 has the second ferromagnetic layer 2 (magnetization fixed layer) located at a position farther from the substrate Sub than the first ferromagnetic layer 1 and is referred to as a top pin structure.

In addition, the first conductor 40 and the second conductor 50 are connected to at least some of the plurality of projecting portions 31 below the spin-orbit torque wiring 20. The first conductor 40 and the second conductor 50 extend downward from the spin-orbit torque wiring 20.

The magnetoresistance effect element 104 according to the fifth embodiment exhibits effects similar to those of the magnetoresistance effect element 100 according to the first embodiment.

### Sixth Embodiment

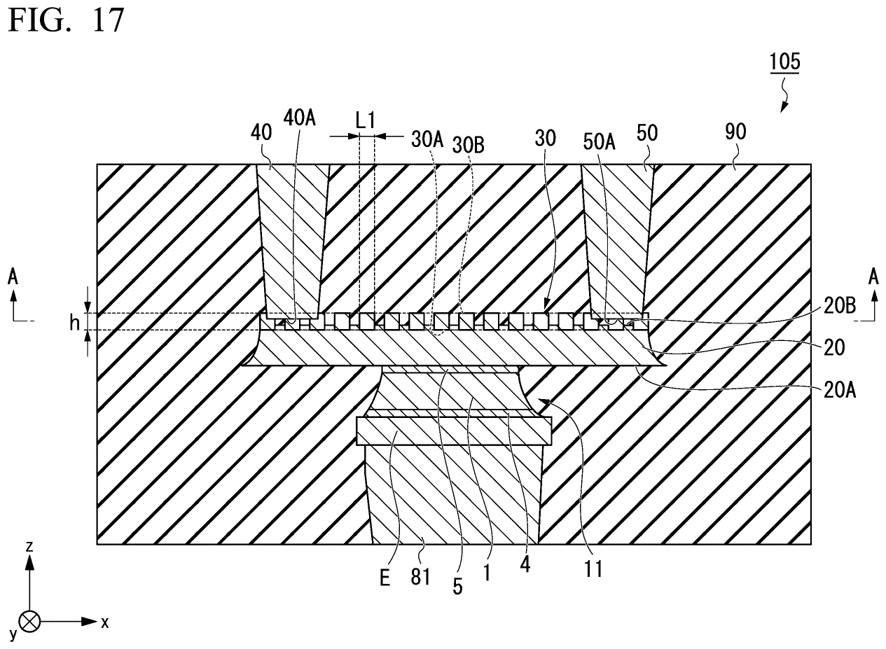

FIG. 17 is a cross-sectional view of a magnetization rotation element 105 according to a sixth embodiment. The magnetoresistance effect element 100 in FIG. 1 is replaced with the magnetization rotation element 105. The magnetization rotation element 105 differs from the magnetoresistance effect element 100 in that a laminate 11 does not have the second ferromagnetic layer 2 and the nonmagnetic layer 3. In the magnetization rotation element 105, similar reference signs are applied to constituents similar to those in the magnetoresistance effect element 100, and a description thereof will be omitted. The magnetization rotation element 105 is an example of a magnetic element.

For example, in the magnetization rotation element 105, light is incident on the first ferromagnetic layer 1, and the light reflected by the first ferromagnetic layer 1 is evaluated. If the orientation direction of the magnetization changes due to the magnetic Kerr effect, the deflection state of the reflected light changes. For example, the magnetization rotation element 105 can be used as an optical element, such as a video image display device, utilizing the difference in deflection state of light, for example.

Furthermore, the magnetization rotation element 105 can also be utilized alone as an anisotropic magnetic sensor, an optical element utilizing the magnetic Faraday effect, or the like.

The magnetization rotation element 105 according to the sixth embodiment is realized by simply removing the nonmagnetic layer 3 and the second ferromagnetic layer from the magnetoresistance effect element 100, and effects similar to those of the magnetoresistance effect element 100 according to the first embodiment can be achieved.

Thus far, preferred aspects of the present invention have been described with several exemplary embodiments, but the present invention is not limited to these embodiments. For example, characteristic constitutions in each of the embodiments may be applied to other embodiments.

### REFERENCE SIGNS LIST

1, 91 First ferromagnetic layer
2, 92 Second ferromagnetic layer
3, 93 Nonmagnetic layer
4, 94 Base layer
5, 95 Cap layer
10, 11 Laminate
20 Spin-orbit torque wiring
20A, 30A, 33A, 36A, 40A, 41A, 50A, 51A First surface
20B, 30B, 33B, 36B Second surface
30, 33, 36 Heat dissipation structure
31, 34 Projecting portion
32, 35 Insulating portion
37 Void
40, 41 First conductor
50, 51 Second conductor
81, 82, 83, 84 Via wiring
85 In-plane wiring
90 Insulating layer
96 Spin-orbit torque wiring layer
97 Sacrificial layer
98 Heat dissipation layer
100, 101, 102, 103, 104 Magnetoresistance effect element
105 Magnetization rotation element
200 Magnetic array
H1, H2 Opening

1. A magnetic element comprising:
a spin-orbit torque wiring;
a laminate connected to a first surface of the spin-orbit torque wiring and including a first ferromagnetic layer;
a heat dissipation structure having a plurality of projecting portions protruding in a lamination direction from a second surface opposing the first surface of the spin-orbit torque wiring; and
a first conductor coming into contact with at least one of the plurality of projecting portions and electrically connected to the spin-orbit torque wiring.

2. The magnetic element according to claim 1 further comprising:
a second conductor,
wherein the second conductor comes into contact with at least one of the plurality of projecting portions and is electrically connected to the spin-orbit torque wiring.

3. The magnetic element according to claim 1,
wherein in the lamination direction, a first surface of the first conductor on a side closer to the spin-orbit torque wiring is closer to the spin-orbit torque wiring than a second surface opposing a first surface of the heat dissipation structure coming into contact with the spin-orbit torque wiring.

4. The magnetic element according to claim 1,
wherein in the lamination direction, a first surface of the heat dissipation structure coming into contact with the spin-orbit torque wiring is closer to the laminate than the second surface of the spin-orbit torque wiring.

5. The magnetic element according to claim 1,
wherein a resistivity of the plurality of projecting portions is higher than a resistivity of the spin-orbit torque wiring.

6. The magnetic element according to claim 1,
wherein each of the plurality of projecting portions is a crystal grain.

7. The magnetic element according to claim 1,
wherein the spin-orbit torque wiring has a longer length in a first direction than a length in a second direction orthogonal to the first direction within a plane orthogonal to the lamination direction, and
an average height of the plurality of projecting portions is shorter than an average length of the plurality of projecting portions in the first direction.

8. The magnetic element according to claim 1.
wherein the spin-orbit torque wiring has a longer length in a first direction than a length in a second direction orthogonal to the first direction within a plane orthogonal to the lamination direction,
the plurality of projecting portions are discontinuous in the first direction, and
an average length of the plurality of projecting portions in the second direction is longer than an average length of the plurality of projecting portions in the first direction.

9. The magnetic element according to claim 1,
wherein the heat dissipation structure has voids being in a vacuum state or filled with a gas between adjacent projecting portions.

10. The magnetic element according to claim 1,
wherein the laminate further includes a second ferromagnetic layer and a nonmagnetic layer,
the first ferromagnetic layer and the second ferromagnetic layer sandwich the nonmagnetic layer therebetween in the lamination direction, and
the first ferromagnetic layer is closer to the spin-orbit torque wiring than the second ferromagnetic layer.

11. A magnetic array comprising:
the magnetic element according to claim 1.

12. A method for manufacturing a magnetic element comprising:
a step of laminating a laminate including a first ferromagnetic layer;
a step of film-forming a spin-orbit torque wiring on the laminate;
a step of pattern forming of a sacrificial layer on the spin-orbit torque wiring;
a step of film-forming a heat dissipation layer on the spin-orbit torque wiring and the sacrificial layer;
a step of forming a heat dissipation structure having a plurality of projecting portions by lifting off a part of the heat dissipation layer together with the sacrificial layer; and
a step of forming an opening at a position overlapping at least one of the plurality of projecting portions and filling the opening with a conductor.
